(19) United States
(12) Patent Application Publication
(10) Pub. No.: US 2023/0196163 A1
(43) Pub. Date: Jun. 22, 2023

(54) SHIELDED SUPERCONDUCTING QUBIT WITH IMPROVED COHERENCE

(71) Applicant: International Business Machines Corporation, Armonk, NY (US)

(72) Inventors: Harry Jonathon Mamin, Palo Alto, CA (US); Timothy Phung, Milpitas, CA (US); Daniel Rugar, Los Altos, CA (US)

(21) Appl. No.: 17/644,900

(22) Filed: Dec. 17, 2021

(51) Int. Cl. G06N 10/40; G06N 10/20; H01L 23/522

(52) U.S. Cl. CPC G06N 10/40; G06N 10/20; H01L 23/5225

(57) ABSTRACT

Techniques regarding shielded superconducting qubits are provided. For example, one or more embodiments described herein can include an apparatus that can comprise a superconducting qubit positioned adjacent to a superconducting ground plane on a substrate. Also, the apparatus can comprise a superconducting shield layer positioned between the superconducting qubit and the superconducting ground plane.

### BACKGROUND

The subject disclosure relates to shielded superconducting qubits, and more specifically, to quantum circuit architecture that includes a shield layer at least partially surrounding a superconducting qubit (e.g., a transmon qubit).

Superconducting qubits can be driven by differential resonators to enhance their quality factor. Additionally, increasing the dimensions of superconducting qubits can also enhance the quality factor. For instance, increasing the physical dimensions of the superconducting qubits can lower surface participation and improve the coherence of the superconducting qubits. However, increasing the size the superconducting qubits can lead to large dipole moments and higher radiative loss. Further, increasing the size of the superconducting qubits can cause increased coupling between the superconducting qubit and a surrounding ground plane of the quantum circuit; thereby causing leakage of the qubit energy.

### SUMMARY

The following presents a summary to provide a basic understanding of one or more embodiments of the invention. This summary is not intended to identify key or critical elements, or delineate any scope of the particular embodiments or any scope of the claims. Its sole purpose is to present concepts in a simplified form as a prelude to the more detailed description that is presented later. In one or more embodiments described herein, apparatuses, devices, and/or methods regarding shielded superconducting qubits are described.

According to an embodiment, an apparatus is provided. The apparatus can comprise a superconducting qubit positioned adjacent to a superconducting ground plane on a substrate. The apparatus can also comprise a superconducting shield layer positioned between the superconducting qubit and the superconducting ground plane. An advantage of such an apparatus can be the reduction of a dipole moment of the superconducting qubit via the superconducting shield layer.

In some examples, the superconducting shield layer can be entrenched within the substrate. An advantage of such an apparatus can be additional screening of the electric field of the superconducting qubit.

According to an embodiment, a device is provided. The device can comprise a superconducting shield layer positioned between a superconducting qubit and a superconducting ground plane. The superconducting shield layer can comprise a material that inhibits a coupling interaction between the superconducting qubit and the superconducting ground plane. An advantage of such a device can be a reduction in qubit energy leakage with regards to the superconducting ground plane.

In some examples, the superconducting qubit and the superconducting ground plane can be positioned on a substrate. Also, the superconducting shield layer can be positioned on a surface of the substrate between the superconducting qubit and the superconducting ground plane. An advantage of such a device can be an enhanced screening of the electric field of the superconducting qubit by the superconducting shield layer.

According to an embodiment, a method is provided. The method can comprise improving coherence of a superconducting qubit by providing a superconducting shield layer between the superconducting qubit and a superconducting ground plane. The superconducting shield layer can screen an electric field and reduces an overall dipole moment of the superconducting qubit. An advantage of such a method can be the inhibition of a coupling interaction between the superconducting qubit and the superconducting ground plane.

In some examples, the method can also comprise mitigating crosstalk between the superconducting qubit and another superconducting qubit via the superconducting shield layer. An advantage of such a method can be the ability to achieve multiple quantum gates with high fidelity before loss of coherence.

### BRIEF DESCRIPTION OF THE DRAWINGS

FIG. 1 illustrates a diagram of an example, non-limiting top-down view of a quantum circuit architecture comprising a superconducting qubit at least partially surrounded by one or more shield layers in accordance with one or more embodiments described herein.

FIG. 2 illustrates a diagram of an example, non-limiting cross-sectional view of a quantum circuit architecture comprising a superconducting qubit at least partially surrounded by one or more shield layers in accordance with one or more embodiments described herein.

FIG. 3 illustrates a diagram of an example, non-limiting cross-sectional view of a quantum circuit architecture comprising a superconducting qubit at least partially surrounded by one or more entrenched shield layers in accordance with one or more embodiments described herein.

FIG. 4 illustrates a diagram of an example, non-limiting top-down view of a quantum circuit architecture comprising a superconducting qubit at least partially surrounded by one or more shield layers and coupled to one or more transmission lines in accordance with one or more embodiments described herein.

FIGS. 5A-5B illustrate diagrams of an example, non-limiting quantum circuit architecture comprising a superconducting qubit at least partially surrounded by one or more entrenched shield layers and coupled to one or more transmission lines in accordance with one or more embodiments described herein.

FIG. 6 illustrates a diagram of an example, non-limiting three-dimensional (“3D”) view of a quantum circuit architecture comprising a superconducting qubit at least partially surrounded by one or more entrenched shield layers and coupled to one or more transmission lines in accordance with one or more embodiments described herein.

FIG. 7 illustrates a diagram of an example, non-limiting top-down view of a quantum circuit architecture comprising two superconducting qubits at least partially surrounded by respective shield layers in accordance with one or more embodiments described herein.

FIG. 8 illustrates a diagram of an example, non-limiting graph that can characterize crosstalk between multiple superconducting qubits in various quantum circuit architectures in accordance with one or more embodiments described herein.

FIG. 9 illustrates a flow diagram of an example, non-limiting method that can facilitate improving the coherence and/or reducing the crosstalk of superconducting qubits in accordance with one or more embodiments described herein.

### DETAILED DESCRIPTION

The following detailed description is merely illustrative and is not intended to limit embodiments and/or application or uses of embodiments. Furthermore, there is no intention to be bound by any expressed or implied information presented in the preceding Background or Summary sections, or in the Detailed Description section.

One or more embodiments are now described with reference to the drawings, wherein like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details.

Given the problems with other implementations of quantum circuit architectures; the present disclosure can be implemented to produce a solution to one or more of these problems by shielding one or more superconducting qubits to mitigate coupling with a superconducting ground plane. Advantageously, one or more embodiments described herein can achieve superconducting qubits with large physical dimensions while improving coherence and mitigating crosstalk. Further, one or more embodiments described herein can leverage the radiative loss screening provided by a superconducting ground plane while mitigating qubit energy leakage to the superconducting ground plane.

Various embodiments described herein can regard a quantum circuit architecture comprising one or more shield layers at least partially surrounding one or more superconducting qubits (e.g., a transmon qubit). For example, the one or more superconducting qubits can be differentially driven, and/or the one or more shield layers can be positioned between the one or more superconducting qubits and a superconducting ground plane. Further, the one or more shield layers can be electrically isolated from the superconducting ground plane. Thereby, the one or more shield layers can mitigate coupling between the one or more superconducting qubits and the superconducting ground plane. In one or more embodiments, the one or more shield layers can be positioned on the surface of a substrate of the quantum circuit architecture. Further, in one or more embodiments, the one or more shield layers can extend into the substrate (e.g., can be entrenched within the substrate).

As described herein, the terms “deposition process” and/or “deposition processes” can refer to any process that grows, coats, deposits, and/or otherwise transfers one or more first materials onto one or more second materials. Example deposition processes can include, but are not limited to: physical vapor deposition (“PVD”), chemical vaper deposition (“CVD”), electrochemical deposition (“ECD”), atomic layer deposition (“ALD”), low-pressure chemical vapor deposition (“LPCVD”), plasma enhanced chemical vapor deposition (“PECVD”), high density plasma chemical vapor deposition (“HDPCVD”), sub-atmospheric chemical vapor deposition (“SACVD”), rapid thermal chemical vapor deposition (“RTCVD”), in-situ radical assisted deposition, high temperature oxide deposition (“HTO”), low temperature oxide deposition (“LTO”), limited reaction processing CVD (“LRPCVD”), ultrahigh vacuum chemical vapor deposition (“UHVCVD”), metalorganic chemical vapor deposition (“MOCVD”), physical vapor deposition (“PVD”), chemical oxidation, sputtering, plating, evaporation, spin-on-coating, ion beam deposition, electron beam deposition, laser assisted deposition, chemical solution deposition, a combination thereof, and/or the like.

As described herein, the terms “etching process”, “etching process”, “removal process”, and/or “removal processes” can refer to any process that removes one or more first materials from one or more second materials. Example etching and/or removal processes can include, but are not limited to: wet etching, dry etching (e.g., reactive ion etching (“RIE”)), chemical-mechanical planarization (“CMP”), a combination thereof, and/or the like.

As described herein, the terms “lithography process” and/or “lithography processes” can refer to the formation of three-dimensional relief images or patterns on a semiconductor substrate for subsequent transfer of the pattern to the substrate. In semiconductor lithography, the patterns can be formed by a light sensitive polymer called a photo-resist. To build the complex structures that make up a semiconductor device and the many wires that connect the various features of a circuit, lithography processes and/or etch pattern transfer steps can be repeated multiple times. Each pattern being printed on the wafer can be aligned to the previously formed patterns and slowly the subject features (e.g., conductors, insulators and/or selectively doped regions) can be built up to form the final device.

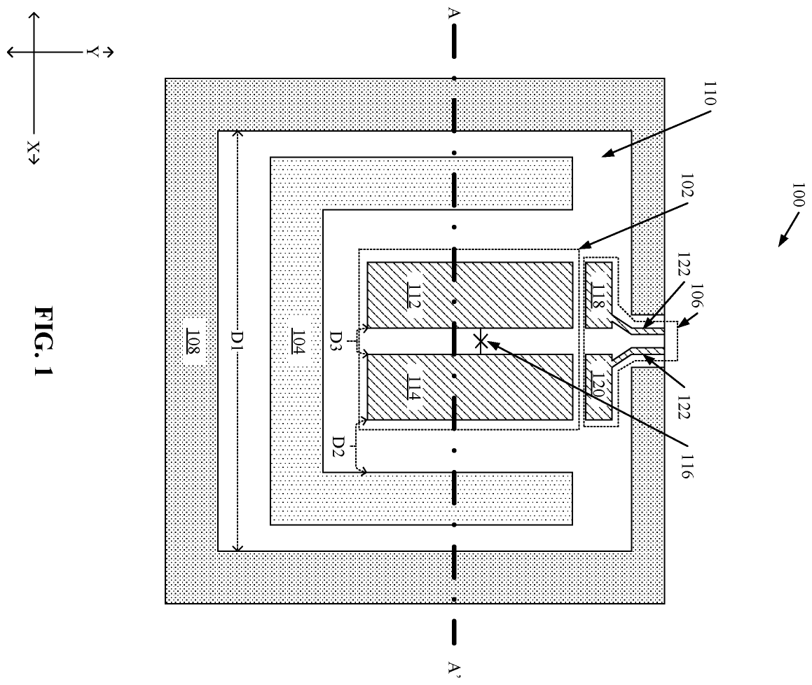

FIG. 1 illustrates a diagram of an example, non-limiting quantum circuit architecture 100 comprising one or more superconducting qubits 102 (e.g., one or more transmon qubits) at least partially surrounded by one or more shield layers 104 in accordance with one or more embodiments described herein. Repetitive description of like elements employed in other embodiments described herein is omitted for the sake of brevity. FIG. 1 depicts a top-down view of the quantum circuit architecture 100. As shown in FIG. 1, the one or more superconducting qubits 102 can be operatively coupled (e.g., capacitively coupled) to a differential resonator circuitry 106. Further, the one or more shield layers 104 can be positioned between the one or more superconducting qubits 102 and a superconducting ground plane 108. In various embodiments, the one or more superconducting qubits 102, one or more shield layers 104, differential resonator circuitry 106, and/or superconducting ground plane 108 can be positioned on a substrate 110.

In one or more embodiments, the substrate 110 can support the one or more superconducting qubits 102, one or more shield layers 104, differential resonator circuitry 106, and/or superconducting ground plane 108. The substrate 110 can comprise essentially (e.g., except for contaminants) a single element (e.g., silicon or germanium) and/or a compound, such as silicon germanium or sapphire. Additionally, the substrate 110 can comprise multiple layers. In one or more embodiments, the substrate 110 can be a silicon wafer. In various embodiments, the substrate 110 can comprise a single crystal silicon (Si), silicon germanium (e.g., characterized by the chemical formula SiGe), a Group III-V semiconductor wafer or surface/active layer, a combination thereof, and/or the like. The dimensions of the substrate 110 can vary depending on the number and/or architecture of the one or more quantum circuit architecture 100 and/or the application of the quantum circuit architecture 100.

The one or more superconducting qubits 102 (e.g., denoted by dotted lines in FIG. 1) can comprise a first superconducting pad 112, a second superconducting pad 114, and/or one or more Josephson junctions 116 (e.g., denoted by the “X” in FIG. 1). For example, superconducting qubits 102 can be lithographically defined (e.g., via one or more lithography processes) electronic circuits that can be cooled to milli-Kelvin temperatures to exhibit quantized energy levels (e.g., due to the quantum mechanical nature of the electronic charge and the superconducting phase, which can depend on quantized states of electronic charge or magnetic flux). Superconducting qubits 102 can be Josephson junction-based, such as transmon qubits and/or the like (e.g., as shown in FIG. 1). Also, the superconducting qubits 102 can be compatible with microwave control electronics, and can be utilized with gate-based technology or integrated cryogenic controls. As described herein the term “superconducting” can characterize a material that exhibits superconducting properties at or below a superconducting critical temperature, such as aluminum (e.g., superconducting critical temperature of 1.2 Kelvin) or niobium (e.g., superconducting critical temperature of 9.3 Kelvin). Additionally, one of ordinary skill in the art will recognize that other superconductor materials (e.g., hydride superconductors, such as lithium/magnesium hydride alloys) can be used in the various embodiments described herein.

For example, the first superconducting pad 112 can comprise one or more superconducting materials, including, but not limited to: niobium, aluminum, titanium, tantalum, tungsten, molybdenum, nitrides of the same, a combination thereof, and/or the like. Also, the second superconducting pad 114 can comprise one or more superconducting materials, including, but not limited to: niobium, aluminum, titanium, tantalum, tungsten, molybdenum, nitrides of the same, a combination thereof, and/or the like. In one or more embodiments, the first superconducting pad 112 and the second superconducting pad 114 can have the same, or substantially the same, composition. In one or more embodiments, the first superconducting pad 112 and the second superconducting pad 114 can have different compositions. As shown in FIG. 1, one or more Josephson junctions 116 can be formed between the first superconducting pad 112 and the second superconducting pad 114.

In one or more embodiments, the differential resonator circuitry 106 can be capacitively coupled to the one or more superconducting qubits 102 via a first superconducting capacitor pad 118 and/or a second superconducting capacitor pad 120. The first superconducting capacitor pad 118 can comprise one or more superconducting materials, including, but not limited to: niobium, aluminum, titanium, tantalum, tungsten, molybdenum, nitrides of the same, a combination thereof, and/or the like. Also, the second superconducting capacitor pad 120 can comprise one or more superconducting materials, including, but not limited to: niobium, aluminum, titanium, tantalum, tungsten, molybdenum, nitrides of the same, a combination thereof, and/or the like. In one or more embodiments, the first superconducting capacitor pad 118 and the second superconducting capacitor pad 120 can have the same, or substantially the same, composition. Further, the first superconducting capacitor pad 118 and/or second superconducting capacitor pad 120 can be coupled to one or more superconducting circuitry 122. The superconducting circuitry 122 can comprise one or more superconducting materials, including, but not limited to: niobium, aluminum, titanium, tantalum, tungsten, molybdenum, nitrides of the same, a combination thereof, and/or the like. As shown in FIG. 1, the differential resonator circuitry 106 can be positioned adjacent to the one or more superconducting qubits 102, and/or can be employed to drive the one or more superconducting qubits 102 via one or more microwave signals.

In one or more embodiments, the superconducting ground plane 108 can be positioned on the substrate 110 and at least partially surrounding the one or more superconducting qubits 102. In various embodiments, the superconducting ground plane 108 can screen radiative loss to enhance the quality factor (e.g., the coherence) of the one or more superconducting qubits 102. The superconducting ground plane 108 can comprise one or more superconducting materials, including, but not limited to: niobium, aluminum, titanium, tungsten molybdenum, nitrides of the same, a combination thereof, and/or the like. In one or more embodiments, the superconducting ground plane 108 can have the same, or substantially the same, material composition as the one or more superconducting qubits 102. In one or more embodiments, the superconducting ground plane 108 can have a different material composition than the one or more superconducting qubits 102. In one or more embodiments, a first distance D1 spanning from one interior boundary of the superconducting ground plane 108 to an opposite interior boundary of the superconducting ground plane 108 can range from, for example, greater than or equal to 5 micrometers and less than or equal to 1000 micrometers.

In one or more embodiments, the one or more shield layers 104 can be positioned between the one or more superconducting qubits 102 and the superconducting ground plane 108. For example, the one or more shield layers 104 can be positioned on the substrate 110 and between the one or more superconducting qubits 102 and the superconducting ground plane 108. In another example, the one or more shield layers 104 can extend into the substrate 110. In one or more embodiments, the one or more shield layers 104 can at least partially surround the one or more superconducting qubits 102. For example, the one or more shield layers 104 can be present on at least two, three, or four sides of the one or more superconducting qubits 102 along the “Y” and/or “X” axes shown in FIG. 1. In various embodiments, the one or more shield layers 104 can extend continuous, or near continuously, around the one or more superconducting qubits 102. In one or more embodiments, the one or more shield layers 104 can comprise one or more gaps and/or spaces.

In one or more embodiments, the one or more shield layers 104 can be spaced from the one or more superconducting qubits 102 by a second distance D2 that can range from, for example, greater than or equal to 1 micrometer and less than or equal to 200 micrometers. Also, while FIG. 1 depicts the one or more shield layers 104 positioned in a rectangular pattern on the substrate 110; the architecture of the quantum circuit architecture 100 is not so limited. For example, embodiments in which the one or more shield layers 104 can be positioned in one or more curved and/or circular patterns around the one or more superconducting qubits 102 are also envisaged. In one or more embodiments, the first superconducting pad 112 and the second superconducting pad 114 can be spaced apart by a third distance D3. In various embodiments, the second distance D2 can range from, for example, 0.2 to 10 times the third distance D3.

Further, the one or more shield layers 104 can comprise one or more superconducting materials, including, but not limited to: niobium, aluminum, titanium, tantalum, tungsten, molybdenum, nitrides of the same, a combination thereof, and/or the like. In various embodiments, the one or more shield layers 104 can suppress and/or otherwise mitigate one or more coupling interactions between the one or more superconducting qubits 102 and the superconducting ground plane 108. For example, the one or more shield layers 104 can be electrically isolated from the superconducting ground plane 108. For instance, the one or more shield layers 104 can be spaced from the superconducting ground plane 108 to avoid direct contact and/or electrical coupling with the superconducting ground plane 108.

In one or more embodiments, the one or more superconducting qubits 102, one or more shield layers 104, differential resonator circuitry 106, and/or superconducting ground plane 108 can be formed on the substrate 110 via one or more deposition processes and/or lithography processes. For example, one or more lithography process can be employed to pattern the one or more superconducting qubits 102, one or more shield layers 104, differential resonator circuitry 106, and/or superconducting ground plane 108 on the substrate 110.

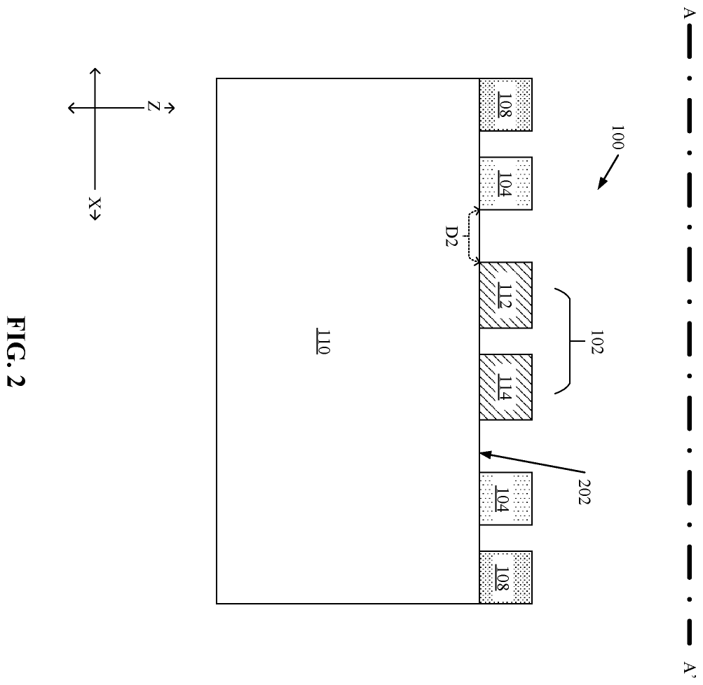

FIG. 2 illustrates a diagram of an example, non-limiting cross-sectional view of the quantum circuit architecture 100 along the A-A′ plane shown in FIG. 1 in accordance with one or more embodiments described herein. Repetitive description of like elements employed in other embodiments described herein is omitted for the sake of brevity. As shown in FIG. 2, the one or more superconducting qubits 102, the one or more shield layers 104, and/or the superconducting ground plane 108 can be positioned on a surface 202 of the substrate 110.

In various embodiments, the dimensions of the one or more superconducting qubits 102, the one or more shield layers 104, and/or the superconducting ground plane 108 can varying depending on the application of the quantum circuit architecture 100. For instance, the first superconducting pad 112 and/or the second superconducting pad 114 can have a width (e.g., along the “X” axis shown in FIG. 2) ranging from, for example, greater than or equal to 1 micrometer and less than or equal to 500 micrometers. Also, the first superconducting pad 112 and/or the second superconducting pad 114 can have a thickness (e.g., along the “Z” axis shown in FIG. 2) ranging from, for example, greater than or equal to 5 nanometers and less than or equal to 1000 nanometers. The one or more shield layers 104 can have a width (e.g., along the “X” axis shown in FIG. 2) ranging from, for example, greater than or equal to 1 micrometer and less than or equal to 400 micrometers. Also, the one or more shield layers 104 can have a thickness (e.g., along the “Z” axis shown in FIG. 2) ranging from, for example, greater than or equal to 5 nanometers and less than or equal to 1000 nanometers. Further, the superconducting ground plane 108 can have a thickness (e.g., along the “Z” axis shown in FIG. 2) ranging from, for example, greater than or equal to 5 nanometers and less than or equal to 1000 nanometers.

While FIG. 2 illustrates the one or more shield layers 104 as comprising a single layer of superconducting material, the architecture of the one or more shield layers 104 is not so limited. Embodiments in which the one or more shield layers 104 comprise a plurality of layers of superconducting materials are also envisaged. Further, while FIG. 2 illustrates the one or more shield layers 104 extending from the substrate 110 to a height (e.g., along the “Z” axis shown in FIG. 2) that is equal to, or substantially equal to, the height of the one or more superconducting qubits 102, the architecture of the one or more shield layers 104 is not so limited. For instance, in one or more embodiments, the one or more shield layers 104 can extend from the surface 202 of the substrate 110 to a height (e.g., along the “Z” axis shown in FIG. 2) that is less than or greater than the one or more superconducting qubits 102.

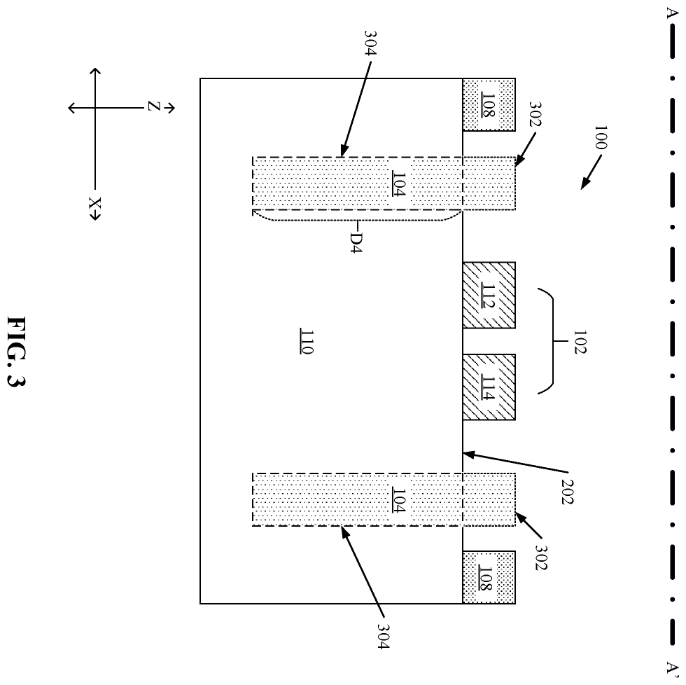

FIG. 3 illustrates a diagram of an example, non-limiting cross-sectional view of the quantum circuit architecture 100 comprising one or more entrenched shield layers 104 along the A-A′ plane shown in FIG. 1 in accordance with one or more embodiments described herein. Repetitive description of like elements employed in other embodiments described herein is omitted for the sake of brevity. As shown in FIG. 3, the one or more shield layers 104 can extend into the substrate 110.

In one or more embodiments, a first portion 302 (e.g., denoted with dotted lines in FIG. 3) of the one or more shield layers 104 can be positioned on and/or above the surface 202 of the substrate 110; while a second portion 304 (e.g., denoted with dashed lines in FIG. 3) of the one or more shield layers 104 can extend below the surface 202 and into the substrate 110. For instance, the one or more shield layers 104 can extend into the substrate 110 by a fourth distance D4 ranging from, for example, greater than or equal to 1 micrometer and less than or equal to 1000 micrometers. Thus, at least a portion of the one or more shield layers 104 can be entrenched within the substrate 110, and/or at least partially surround the one or more superconducting qubits 102. In another embodiment, the shield layer 104 could penetrate completely through the substrate layer 110.

In one or more embodiments, the one or more entrenched shield layers 104 can be formed via one or more etching processes, deposition processes, and/or lithography processes. For example, one or more etching processes can be employed to form one or more trenches into the surface 202 of the substrate 110 (e.g., in accordance with one or more desired patterns). Further, one or more deposition processes can be employed to fill the one or more trenches with superconducting material to form at least the second portion 304 of the one or more shield layers 104.

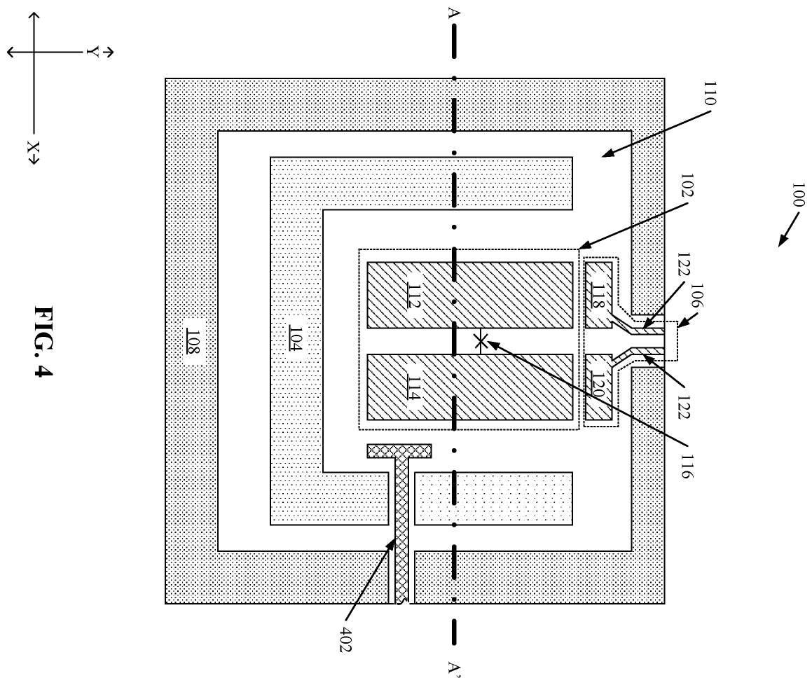

FIG. 4 illustrates a diagram of an example, non-limiting top-down view of the quantum circuit architecture 100 further comprising one or more transmission lines 402 operatively coupled to the one or more superconducting qubits 102 in accordance with one or more embodiments described herein. Repetitive description of like elements employed in other embodiments described herein is omitted for the sake of brevity. The one or more transmission lines 402 can extend through one or more openings in the superconducting ground plane 108. In one or more embodiments, the one or more transmission lines 402 can facilitate a coupling between the one or more superconducting qubits 102 and one or more other superconducting qubits. In various embodiments, the one or more transmission lines 402 can be capacitively coupled to the one or more superconducting qubits 102. Further, the one or more transmission lines 402 can comprise one or more superconducting materials, including, but not limited to: niobium, aluminum, titanium, tantalum, tungsten molybdenum, nitrides of the same, a combination thereof, and/or the like.

As shown in FIG. 4, the one or more transmission lines 402 can extend through a gap in the one or more shield layers 104 to operatively couple with the one or more superconducting qubits 102. For example, the one or more shield layers 104 can extend around the one or more superconducting qubits 102 in a non-continuous pattern on the surface 202 of the substrate 110, where the one or more transmission lines 402 can be positioned on the substrate 110 in a location between sections of the one or more shield layers 104. In various embodiments, the one or more transmission lines 402 can continue to extend beyond the superconducting ground plane 108 to one or more other quantum circuit components, such as one or more other superconducting qubits.

Although FIG. 4 illustrates the one or more shield layers 104 positioned around three sides of the one or more superconducting qubit 102, the structure of the quantum circuit architecture 100 is not so limited. For example, the one or more shield layers 104 can surround the one or more superconducting qubits 102 on all four sides along the Y and/or X axis shown in FIG. 4. Further, the one or more superconducting circuitry 122 can extend through one or more additional gaps in the one or more shied layers 104, where the first superconducting capacitor pad 118 and/or the second superconducting capacitor pad 120 can be positioned between the one or more superconducting qubits 102 and shielding layers 104.

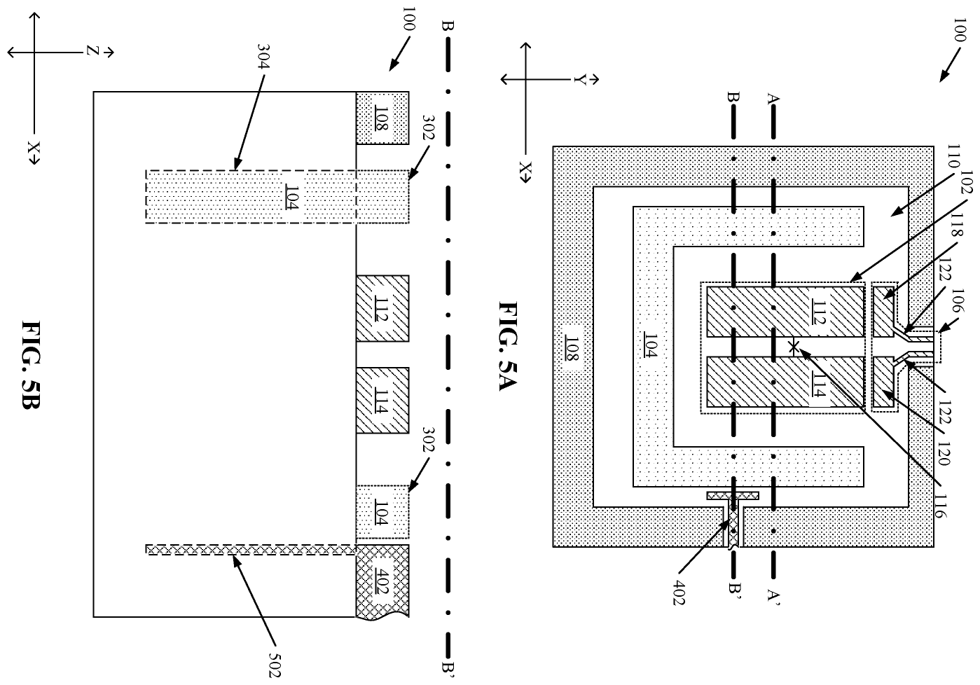

FIG. 5A illustrates a diagram of another example, non-limiting top-down view of the quantum circuit architecture 100 comprising the one or more transmission lines 402 in accordance with one or more embodiments described herein. FIG. 5B illustrates a diagram of an example, non-limiting cross-sectional view of the quantum circuit architecture 100 along the B-B′ plane depicted in FIG. 5A in accordance with one or more embodiments described herein. Repetitive description of like elements employed in other embodiments described herein is omitted for the sake of brevity. As shown in FIGS. 5A-5B, at least a portion (e.g., first portion 302) of the one or more shield layers 104 can extend around the one or more superconducting qubits 102 in a continuous pattern. Further, one or more sections of the one or more shield layers 104 can comprise entrenched portions (e.g., second portion 304), while other sections of the one or more shield layers 104 can lack entrenched portions. Thereby, the one or more shield layers 104 can comprise one or more gaps in the second portion 304. In one or more embodiments, the one or more transmission lines 402 can be aligned with the one or more gaps in the second portion 304 of the one or more shield layers 104 to capacitively couple with the one or more superconducting qubits 102.

For example, FIG. 5B exemplifies that at a position adjacent to the one or more transmission lines 402, the one or more shield layers 104 can be located on the surface 202 of the substrate 110 but not within the substrate 110. Further, at least a portion of the one or more transmission lines 402 can extend below the surface 202 and into the substrate 110. At least because the adjacent section of the one or more shield layers 104 is reserved to the surface 202 of the substrate 110, the entrenched section 502 of the one or more transmission lines 402 can couple with the one or more superconducting qubits 102. For instance, a lack of second portion 304 of the one or more shield layers 104 adjacent to the entrenched section 502 of the one or more transmission lines 402 can enable the coupling between the one or more transmission lines 402 and superconducting qubits 102.

Although FIG. 5A illustrates the one or more shield layers 104 positioned around three sides of the one or more superconducting qubit 102, the structure of the quantum circuit architecture 100 is not so limited. For example, the one or more shield layers 104 can surround the one or more superconducting qubits 102 on all four sides along the Y and/or X axis shown in FIG. 5. Thereby one or more sections of the one or more shielding layers 104 can be positioned adjacent to the first superconducting capacitor 118 and/or the second superconducting capacitor 120. Further, the one or more sections of the one or more shielding layer 104 that are adjacent to the differential resonator circuitry 106 can lack entrenched portions (e.g., second portion 304). Thus, the differential resonator circuitry 106 can align with one or more additional gaps in the second portion 304 of the one or more shielding layers 104 to capacitively couple with the one or more superconducting qubits 102.

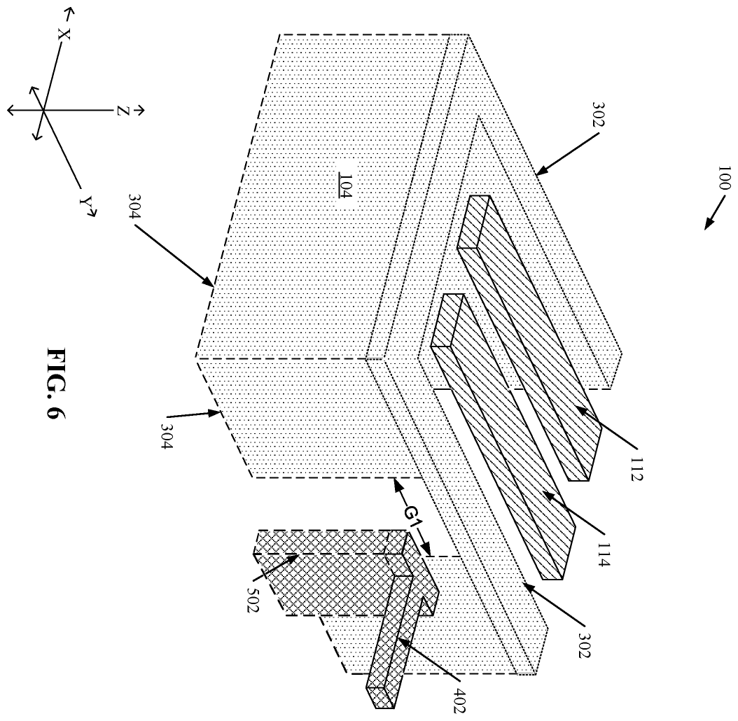

FIG. 6 illustrates a diagram of an example, non-limiting 3D view of the quantum circuit architecture 100 in accordance with one or more embodiments described herein. Repetitive description of like elements employed in other embodiments described herein is omitted for the sake of brevity. For the sake of clarity, the substrate 110, superconducting ground plane 108, and/or differential resonator circuitry 106 are not depicted in FIG. 6. FIG. 6 shows the one or more shield layers 104 comprising one or more gaps G1 located in the second portion 304 in accordance with the embodiments exemplified in FIGS. 5A-5B. In FIG. 6, the first portion 302 (e.g., located on the surface 202 of the substrate 110) of the one or more shield layers 104 is denoted with dotted lines. Also the second portion 304 (e.g., located within the substrate 110) of the one or more shield layers 104 and the entrenched section 502 (e.g., also located within the substrate) of the one or more transmission lines 402 are denoted with dashed lines.

As shown in FIG. 6, the one or more gaps G1 can be aligned with the entrenched section 502 of the one or more transmission lines 402. While a single gap G1 is shown in FIG. 6, the architecture is not so limited. For example, various embodiments can include multiple gaps G1 in the second portion 304 of the one or more shield layers 104. For instance, the one or more superconducting qubits 102 can be coupled to multiple transmission lines 402, where the one or more shield layers 104 can comprise a gap G1 aligned with each transmission line 402. Where the one or more shield layers 104 comprise multiple gaps G1, the dimensions of the gaps G1 can be non-uniform. For example, a first gap G1 in the second portion 304 of the one or more shield layers 104 can be larger or smaller than a second gap G1 in the second portion 304 of the one or more shield layers 104. In another example, a first gap G1 in the second portion 304 of the one or more shield layers 104 can extend to a depth (e.g., along the “Z” axis shown in FIG. 6) within the substrate 110 that is greater than or less than a second gap G1 in the second portion 304 of the one or more shield layers 104.

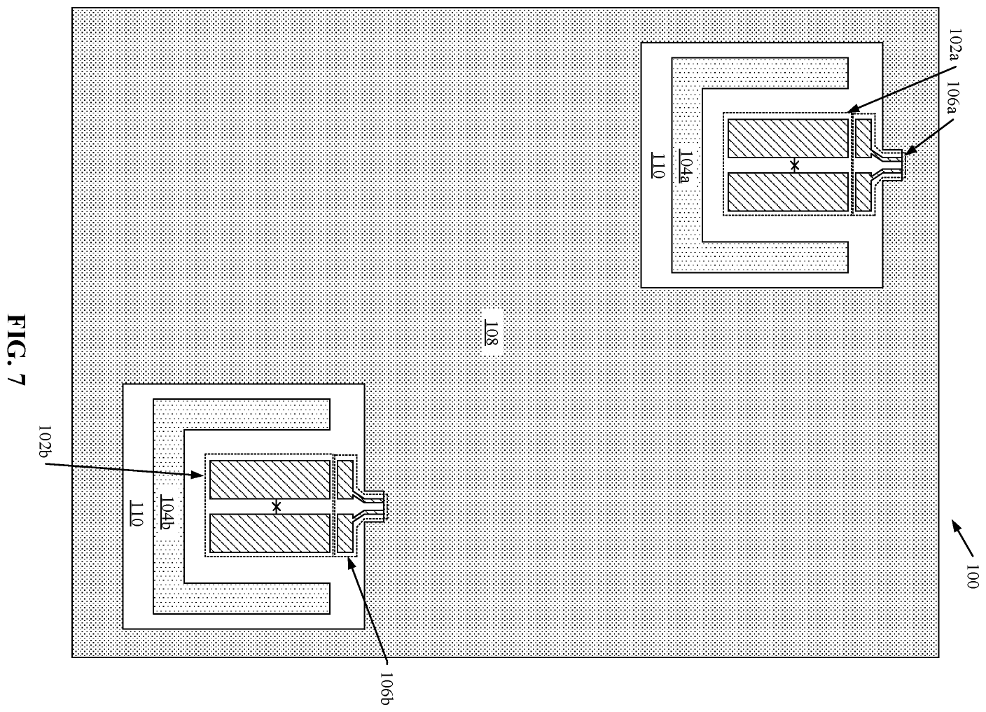

FIG. 7 illustrates a diagram of an example, non-limiting top-down view of the quantum circuit architecture 100 comprising a first superconducting qubit 102a and a second superconducting qubit 102b on a common substrate 110 in accordance with one or more embodiments described herein. Repetitive description of like elements employed in other embodiments described herein is omitted for the sake of brevity. As shown in FIG. 7, multiple superconducting qubits 102 can be positioned on the same substrate 110. Further, each of the superconducting qubits 102 can be at least partially surrounded by one or more shield layers 104 and/or the superconducting ground plane 108.

For instance, a first superconducting qubit 102a can be driven by a first differential resonator circuitry 106a, and/or can be at least partially surrounded by one or more first shield layers 104a (e.g., as shown in FIG. 7). Also, a second superconducting qubit 102b can be driven by a second differential resonator circuitry 106b, and/or can be at least partially surrounded by one or more second shield layers 104b (e.g., as shown in FIG. 7). In one or more embodiments, the superconducting ground plane 108 can surround both the first superconducting qubit 102a and the second superconducting qubit 102b. Thus, an interaction between the first superconducting qubit 102a and the superconducting ground plane 108, and/or an interaction between the second superconducting qubit 102b and the superconducting ground plane 108, can result in crosstalk between the first superconducting qubit 102a and the second superconducting qubit 102b. In various embodiments, the one or more first shield layers 104a can mitigate an interaction between the first superconducting qubit 102a and the superconducting ground plane 108. Further, the one or more second shield layers 104b can mitigate an interaction between the second superconducting qubit 102b and the superconducting ground plane 108.

In one or more embodiments, the quantum circuit architecture 100 can comprise the one or more transmission lines 402 coupled between, for example, the first superconducting qubit 102a and the second superconducting qubit 102b. Further, the one or more first shield layers 104a and/or the one or more second shield layers 104b can comprise one or more gaps G1 aligned with the one or more transmission lines 402 (e.g., as exemplified in FIGS. 4-6).

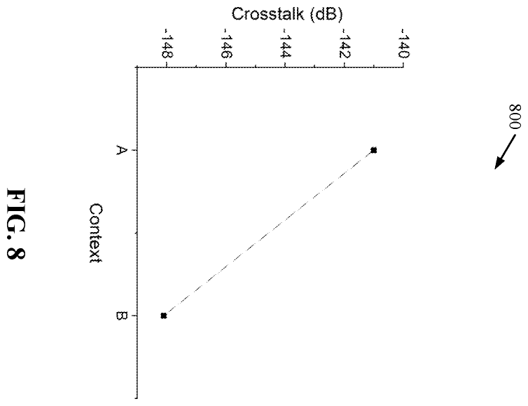

FIG. 8 illustrates a diagram of an example, non-limiting graph 800 that can characterize crosstalk between two superconducting qubits 102 spaced apart on a substrate 110 in accordance with one or more embodiments described herein. Repetitive description of like elements employed in other embodiments described herein is omitted for the sake of brevity. Graph 800 depicts the amount of crosstalk (e.g., in decibels (dB)) between the two superconducting qubits 102 with regards to two contexts, A and B. In context A the two superconducting qubits 102 are arranged in accordance with FIG. 8, except there are no shield layers 104 at least partially surrounding the superconducting qubits 102. In context B, the two superconducting qubits 102 are arranged in accordance with FIG. 8, with the one or more shield layers 104 at least partially surrounding the superconducting qubits 102. As shown in graph 800, the quantum circuit architecture 100 can substantially inhibit crosstalk between the first superconducting qubit 102a and the second superconducting qubit 102b.

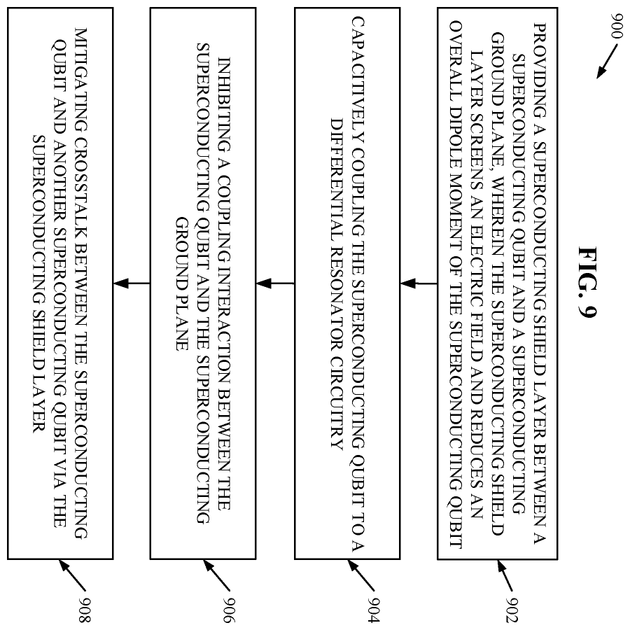

FIG. 9 illustrates a flow diagram of an example, non-limiting method 900 that can facilitate improving the quality factor (e.g., coherence) of one or more superconducting qubits 102 via one or more shield layers 104 in accordance with one or more embodiments described herein. Repetitive description of like elements employed in other embodiments described herein is omitted for the sake of brevity.

At 902, the method 900 can comprise providing one or more superconducting shield layers (e.g., shield layers 104) between one or more superconducting qubits 102 and a superconducting ground plane 108. In various embodiments, the one or more superconducting shield layers (e.g., shield layers 104) can screen an electric field and/or reduce an overall dipole moment of the one or more superconducting qubits 102 (e.g., as exemplified in FIG. 7). In one or more embodiments, the one or more superconducting shield layers (e.g., shield layers 104) can be electrically isolated from the superconducting ground plane 108. Further, the one or more superconducting shield layers (e.g., shield layers 104) can be positioned on, and/or entrenched within, a substrate 110 that is supporting the one or more superconducting qubits 102 and the superconducting ground plane 108.

At 904, the method 900 can comprise capacitively coupling the one or more superconducting qubits 102 to one or more differential resonator circuitry 106. In various embodiments, driving the one or more superconducting qubits 102 via the differential resonator circuitry 106 can enable the use of the one or more shield layers 104 to screen the electric field of the one or more superconducting qubits 102 from the superconducting ground plane 108.

At 906, the method 900 can comprise inhibiting an interaction between the one or more superconducting qubits 102 and the superconducting ground plane 108. For example, at least because the one or more superconducting shield layers (e.g. shield layers 104) can be positioned between the one or more superconducting qubits 102 and the superconducting ground plane 108, the one or more superconducting shield layers (e.g., shield layers 104) can inhibit the electrical field of the one or more superconducting qubits 102 from interacting with the superconducting ground plane 108 (e.g., as shown in FIG. 7).

At 908, the method 900 can comprise mitigating crosstalk between the one or more superconducting qubits 102 and one or more other superconducting qubits 102 via the one or more superconducting shield layers (e.g., shield layers 104). For example, FIG. 7 exemplifies that a first superconducting qubit 102a can be at least partially surrounded by one or more first shield layers 104a. Also, a second superconducting qubit 102b can further be at least partially surrounded by one or more second shield layers 104b. As characterized in graph 800, the respective shield layers 104 can serve to reduce crosstalk between the first superconducting qubits 102a and the second superconducting qubit 102b.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in the subject specification and annexed drawings should generally be construed to mean “one or more” unless specified otherwise or clear from context to be directed to a singular form. As used herein, the terms “example” and/or “exemplary” are utilized to mean serving as an example, instance, or illustration. For the avoidance of doubt, the subject matter disclosed herein is not limited by such examples. In addition, any aspect or design described herein as an “example” and/or “exemplary” is not necessarily to be construed as preferred or advantageous over other aspects or designs, nor is it meant to preclude equivalent exemplary structures and techniques known to those of ordinary skill in the art.

It is, of course, not possible to describe every conceivable combination of components, products and/or methods for purposes of describing this disclosure, but one of ordinary skill in the art can recognize that many further combinations and permutations of this disclosure are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim. The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. An apparatus, comprising:
a superconducting qubit positioned adjacent to a superconducting ground plane on a substrate; and
a superconducting shield layer positioned between the superconducting qubit and the superconducting ground plane.

2. The apparatus of claim 1, wherein the superconducting shield layer reduces a coupling between the superconducting qubit and the superconducting ground plane.

3. The apparatus of claim 1, wherein the superconducting shield layer is entrenched within the substrate.

4. The apparatus of claim 1, wherein the superconducting shield layer comprises a gap located adjacent to a superconducting transmission line operatively coupled to the superconducting qubit.

5. The apparatus of claim 4, wherein the superconducting shield layer comprises a first portion located on a surface of the substrate and a second portion that extends into the substrate, and wherein the gap is located in the second portion.

6. The apparatus of claim 1, wherein the superconducting shield layer at least partially surrounds the superconducting qubit.

7. The apparatus of claim 6, wherein the superconducting qubit is capacitively coupled to differential resonator circuitry.

8. The apparatus of claim 1, wherein the superconducting qubit is a transmon qubit.

9. A device, comprising:
a superconducting shield layer positioned between a superconducting qubit and a superconducting ground plane, wherein the superconducting shield layer comprises a material that inhibits a coupling interaction between the superconducting qubit and the superconducting ground plane.

10. The device of claim 9, wherein the material of the superconducting shield layer further mitigates crosstalk between the superconducting qubit and another superconducting qubit.

11. The device of claim 9, wherein the superconducting shield layer at least partially surrounds the superconducting qubit.

12. The device of claim 9, wherein the superconducting qubit and the superconducting ground plane are positioned on a substrate, and wherein the superconducting shield layer is positioned on a surface of the substrate between the superconducting qubit and the superconducting ground plane.

13. The device of claim 12, wherein a portion of the superconducting shield layer is entrenched within the substrate.

14. The device of claim 9, wherein the superconducting qubit is a transmon qubit.

15. A method, comprising:
improving coherence of a superconducting qubit by providing a superconducting shield layer between the superconducting qubit and a superconducting ground plane, wherein the superconducting shield layer screens an electric field and reduces an overall dipole moment of the superconducting qubit.

16. The method of claim 15, further comprising:
inhibiting a coupling interaction between the superconducting qubit and the superconducting ground plane.

17. The method of claim 15, further comprising:
mitigating crosstalk between the superconducting qubit and another superconducting qubit via the superconducting shield layer.

18. The method of claim 15, wherein the providing the superconducting shield layer between the superconducting qubit and the superconducting ground plane minimizes energy leakage from the superconducting qubit.

19. The method of claim 15, further comprising:
capacitively coupling the superconducting qubit to a differential resonator circuitry.

20. The method of claim 15, wherein the superconducting qubit is a transmon qubit.
